(19) United States
(12) Patent Application Publication
(10) Pub. No.: US 2004/0080025 A1
(43) Pub. Date: Apr. 29, 2004

(54) Lead frame, method of manufacturing the same, and semiconductor device manufactured with the same

(75) Inventors: Tetsuichiro Kasahara, Nagano (JP); Akinobu Abe, Nagano (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: SHINKO ELECTRIC INDUSTRIES CO., LTD., Nagano-shi (JP)

(21) Appl. No.: 10/661,484

(22) Filed: Sep. 15, 2003

(30) Foreign Application Priority Data
Sep. 17, 2002 (JP) 2002-269903

(51) Int. Cl. H01L 21/44; H01L 23/495

(52) U.S. Cl. 257/666; 438/123; 257/676; 257/692

(57) ABSTRACT

In a lead frame, a die-pad portion is defined for a semiconductor element to be mounted, a plurality of wire bonding portions are arranged along a periphery of the die-pad portion within a region to be finally divided as a semiconductor device for the die-pad portion, and a plurality of land-like external terminal portions are arranged in a region outside the wire bonding portions. Furthermore, a plurality of linear connection lead portions are formed to integrally join the wire bonding portions to the respective corresponding external terminal portions. The die-pad portion, the wire bonding portions, the external terminal portions and the connection lead portions are supported by an adhesive tape.

### BACKGROUND OF THE INVENTION

(a) Field of the Invention

The present invention relates to a lead frame used as a substrate of a package (semiconductor device) on which a semiconductor element is mounted. Specifically, the present invention relates to a lead frame which is used in a leadless package such as a Quad Flat Non-leaded (QFN) package and which has a shape adapted for an increase of the number of pins and a decrease of the length of a wire which connects the semiconductor element to an external terminal (pin), and also relates to a method of manufacturing the lead frame, and to a semiconductor device.

(b) Description of the Related Art

As a package with a size nearly equal to that of a semiconductor element (chip), which is called a chip size package or a chip scale package (CSP), there is a package having external terminals exposed to a back surface of the package so as to be flat, such as QFN or a ball grid array (BGA).

FIGS. 1A and 1B schematically show a constitution of a prior art semiconductor device with a QFN package structure. FIG. 1A shows a constitution of a semiconductor device 10 as viewed in a cross section, and FIG. 1B shows the constitution of the semiconductor device 10 as viewed from a back surface (mounting surface). In the semiconductor device 10, reference numeral 11 denotes a semiconductor element (chip) mounted on a die-pad portion 1; reference numeral 12 denotes a bonding wire connecting each of electrode terminals of the semiconductor element 11 to the corresponding lead portion (external connection terminal) 2; and reference numeral 13 denotes sealing resin for protecting the semiconductor element 11, the bonding wire 12, and the like.

The lead portions 2 are exposed to the side of the mounting surface of the semiconductor device 10 and arranged along a periphery of the semiconductor device 10 as shown in the drawing. The die-pad portion 1 and the lead portions 2 arranged therearound consist of part of a lead frame obtained by etching a metal plate or the like, and is defined for a semiconductor element to be mounted on the lead frame. In other words, the QFN (semiconductor device 10) shown in FIG. 1 utilizes the lead frame as its substrate.

Since the prior art QFN is a package (semiconductor device) utilizing the lead frame as described above, it has an advantage in that costs for manufacturing the same are low compared with a substrate type package (semiconductor device) such as BGA which uses a multi-layer wiring board or the like as the substrate of the package, the multi-layer wiring board including insulation layers and conductor layers (wiring layers) alternately stacked.

However, in the prior art QFN (FIG. 1), the external connection terminals (lead portions 2) are not allowed to be arranged under the mounting surface (die-pad portion 1) of the semiconductor element 11, and the arrangement of the external connection terminals has been limited to the periphery of the package (semiconductor device 10).

Therefore, when the number of external terminals (the number of pins) is further increased, it is necessary to narrow both the width of each lead portion and the interval between the lead portions, or to enlarge the size of the package with keeping the size of each lead portion or the like.

However, the technique of narrowing the width of each lead involves a difficulty in a technical aspect (etching of the lead frame, or the like). On the other hand, the technique of enlarging the size of the package has a disadvantage in that a cost of a material (a metal plate of copper (Cu), Cu-based alloy, or the like) constituting the lead frame is increased. In the prior art QFN as shown in FIGS. 1A and 1B, there has been a problem in that the demand for increasing the number of pins (the number of terminals) can not be necessarily satisfied.

As an approach to increase the number of pins, for example, it is conceived that the lead portions (external connection terminals) are arranged in a plurality of rows around the die-pad portion. An example thereof is shown in FIGS. 2A and 2B.

FIGS. 2A and 2B schematically show a constitution of another prior art semiconductor device with a QFN package structure. Similarly to FIGS. 1A and 1B, FIG. 2A shows a constitution of a semiconductor device 10a as viewed in a cross section, and FIG. 2B shows the constitution of the semiconductor device 10a as viewed from a back surface (mounting surface). This semiconductor device 10a differs from the semiconductor device 10 shown in FIGS. 1A and 1B in that lead portions 2a and 2b are arranged in two rows around the die-pad portion 1, and the electrode terminals of the semiconductor element 11 are connected to the lead portions 2a in the inside row and the lead portions 2b in the outside row with bonding wires 12a and 12b, respectively.

According to the constitution of the package (semiconductor device 10a), the number of pins can be increased. However, the size of the package needs to be increased depending on the increased number of pins (the increased number of lead portions), and the bonding wires 12b connecting the electrode terminals of the semiconductor element 11 to the outside lead portions 2b are accordingly lengthened. When the size of the package is increased, there is a disadvantage in that the cost of material of the lead frame is increased as described above.

Moreover, when the wires are lengthened, at the time of resin sealing (molding) of the semiconductor element in an assembly process of the package, the adjacent wires may touch each other by a flowing force of the resin to thereby cause a short-circuit, thus lowering a reliability of the product. As a result, a manufacturing yield is lowered. In addition, since a relatively expensive material such as a gold (Au) wire is used for the bonding wires, there is also a disadvantage in that the material cost thereof is increased.

### SUMMARY OF THE INVENTION

An object of the present invention is to provide a lead frame which enables an increase in the number of pins and a minimization of the length of wires connecting a semiconductor element to be mounted and external terminals, and accordingly contributes to an increase in yield and a reduction in cost, and also to provide a method of manufacturing the lead frame, and a semiconductor device with the same.

To attain the above object, according to a first aspect of the present invention, there is provided a lead frame including: a die-pad portion defined for a semiconductor element to be mounted; a plurality of wire bonding portions arranged along a periphery of the die-pad portion within a region to be finally divided as a semiconductor device for the die-pad portion; a plurality of land-like external terminal portions arranged in a region outside the wire bonding portions; and a plurality of linear connection lead portions each integrally joining each of the wire bonding portions to a corresponding one of the external terminal portions, wherein the die-pad portion, the wire bonding portion and the external terminal portions are supported by an adhesive tape.

According to the a constitution of the lead frame of the first aspect, the plurality of land-like external terminal portions used as the external connection terminals are arranged in the region outside the wire bonding portions which are arranged along the periphery of the die-pad portion defined for a semiconductor element to be mounted. Accordingly, compared with the prior art (FIGS. 1A and 1B) in which the external connection terminals (lead portions) are arranged in a row along the periphery of the package, the number of terminals can be relatively increased (realization of a package with the number of pins increased).

Moreover, in the prior art lead frame used as substrate of QFN, bonding wires have been connected to portions just above the respective lead portions (top surfaces thereof) constituting the external connection terminals (FIGS. 1A and 1B, and FIGS. 2A and 2B). Contrary to this, in the lead frame according to the present invention, the portions to which the bonding wires are connected and the portions used as the external connection terminals are arranged separately from each other, and both of the portions are integrally joined by the respective linear connection lead portions. In this case, the wire bonding portions are arranged along the periphery of the die-pad portion (namely, at positions near the electrode terminals of the semiconductor element to be mounted).

Accordingly, the length of wires between the semiconductor element and the external terminals (namely, the wire bonding portions connected to the external terminal portions) can be minimized. Consequently, the disadvantages such as a short-circuit between wires or a reduction in reliability, as encountered in the prior art, can be eliminated, thus enabling an increase in yield and a reduction in cost.

Also, according to a second aspect of the present invention, there is provided a lead frame including: a plurality of wire bonding portions arranged within a region to be finally divided as a semiconductor device for a semiconductor element to be mounted, and along an outer periphery of the region; a plurality of land-like external terminal portions arranged in a region inside the wire bonding portions; and a plurality of linear connection lead portions each integrally joining each of the wire bonding portions to a corresponding one of the external terminal portions, wherein the wire bonding portions and the external terminal portions are supported by an adhesive tape.

According to the constitution of the lead frame of the second aspect, the plurality of land-like external terminal portions used as the external connection terminals are arranged in the region inside the wire bonding portions which are arranged along the outer periphery of the region to be finally divided as the semiconductor device for a semiconductor element to be mounted. Accordingly, compared with the prior art (FIGS. 1A, 1B, and FIGS. 2A, 2B) in which the external connection terminals cannot be arranged under the mounting surface of the semiconductor element, the number of terminals can be relatively increased (realization of a package with the number of pins increased).

Moreover, similarly to the above described constitution of the lead frame according to the first aspect, the wire bonding portions and the external terminal portions are arranged separately from each other, and both of the portions are integrally joined to each other by the respective linear connection lead portions. In this case, the wire bonding portions are arranged along the outer periphery of the region to be finally divided as the semiconductor device for the semiconductor element to be mounted (namely, arranged at positions near the electrode terminals of the semiconductor element to be mounted). Accordingly, the length of the wires connecting the semiconductor element and the external terminals can be minimized similarly to the first aspect, thus enabling an increase in yield and a reduction in cost.

Also, according to another aspect of the present invention, there is provided a method of manufacturing a lead frame according to the above first or second aspect.

A method of manufacturing the lead frame according to the first aspect includes the steps of: forming a base frame by etching a metal plate, the base frame including a plurality of wire bonding portions, a plurality of land-like external terminal portions and a plurality of linear connection lead portions arranged in a region between a die-pad portion and a frame portion for a semiconductor element to be mounted, said plurality of wire bonding portions being located along a periphery of the die-pad portion and joined to the die-pad portion, said plurality of external terminal portions being located outside the wire bonding portions and joined to each other, said plurality of connection lead portions each integrally joining each of the wire bonding portions to a corresponding one of the external terminal portions; forming recess portions by half etching, in portions other than the die-pad portion, the wire bonding connection portions, the external terminal portions and the frame portion, of one surface of the base frame; attaching an adhesive tape to the surface of the base frame where the recess portions are formed; and cutting off portions joining the die-pad portion and the wire bonding portions, and portions joining the external terminal portions to each other, among the portions of the base frame where the recess portions are formed.

On the other hand, a method of manufacturing the lead frame according to the second aspect includes the steps of: forming a base frame by etching a metal plate, the base frame including a plurality of wire bonding portions, a plurality of land-like external terminal portions and a plurality of linear connection lead portions arranged in a region surrounded by a frame portion for a semiconductor element to be mounted, said plurality of wire bonding portions being located along an outer periphery of the region and joined to the frame portion, said plurality of external terminal portions being located inside the wire bonding portions and joined to each other, said plurality of connection lead portions each integrally joining each of the wire bonding portions to a corresponding one of the external terminal portions; forming recess portions by half etching, in portions other than the external terminal portions, the wire bonding portions and the frame portion, of one surface of the base frame; attaching an adhesive tape to the surface of the base frame where the recess portions are formed; and cutting off portions joining the external terminal portions to each other, among the portions of the base frame where the recess portions are formed.

Also, according to still another aspect of the present invention, there is provided a semiconductor device manufactured with a lead frame according to the above first or second aspect.

A semiconductor device using the lead frame according to the first aspect includes: a die-pad portion; a plurality of wire bonding portions arranged along a periphery of the die-pad portion; a plurality of land-like external terminal portions arranged outside the wire bonding portions; a plurality of linear connection lead portions each integrally joining each of the wire bonding portions to a corresponding one of the external terminal portions; and a semiconductor element mounted on the die-pad portion, wherein each of electrode terminals of the semiconductor element is connected to a top surface of a corresponding one of the wire bonding portions by a bonding wire, the semiconductor element, the bonding wire, the wire bonding portions, the external terminal portions and the connection lead portions are sealed with sealing resin, and bottom surfaces of the external terminal portions are exposed to a surface of the sealing resin together with bottom surfaces of the wire bonding portions.

On the other hand, a semiconductor device using the lead frame according to the second aspect includes: a plurality of wire bonding portions arranged along a periphery of the device; a plurality of land-like external terminal portions arranged inside the wire bonding portions; a plurality of linear connection lead portions each integrally joining each of the wire bonding portions to a corresponding one of the external terminal portions; and a semiconductor element mounted on a required number of external terminal portions among said plurality of external terminal portions, while keeping isolated from the required number of external terminal portions, wherein each of electrode terminals of the semiconductor element is connected to a top surface of a corresponding one of the wire bonding portions by a bonding wire, the semiconductor element, the bonding wire, the wire bonding portions, the external terminal portions and the connection lead portions are sealed with sealing resin, and bottom surfaces of the external terminal portions are exposed to a surface of the sealing resin together with bottom surfaces of the wire bonding portions.

### BRIEF DESCRIPTION OF THE DRAWINGS

FIGS. 1A and 1B are views showing a constitution of a prior art semiconductor device with a QFN package structure;

FIGS. 2A and 2B are views showing a constitution of another prior art semiconductor device with a QFN package structure;

FIGS. 3A and 3B are views showing a constitution of a lead frame according to a first embodiment of the present invention;

FIG. 4 is a plan view showing an example of a manufacturing process of the lead frame of FIGS. 3A and 3B;

FIGS. 5A to 5D are cross-sectional views showing steps following the manufacturing process of FIG. 4;

FIGS. 6A to 6C are cross-sectional views showing another example (part thereof) of the manufacturing process of the lead frame of FIGS. 3A and 3B;

FIGS. 7A and 7B are views showing a constitution of a semiconductor device with a QFN package structure manufactured using the lead frame of FIGS. 3A and 3B;

FIGS. 8A to 8E are cross-sectional views showing a manufacturing process of the semiconductor device of FIGS. 7A and 7B;

FIGS. 9A and 9B are views showing a constitution of a lead frame according to a second embodiment of the present invention;

FIG. 10 is a plan view showing an example of a manufacturing process of the lead frame of FIGS. 9A and 9B;

FIGS. 11A to 11D are cross-sectional views showing steps following the manufacturing process of FIG. 10;

FIGS. 12A and 12B are views showing a constitution of a semiconductor device with a QFN package structure manufactured using the lead frame of FIGS. 9A and 9B; and

FIGS. 13A to 13E are cross-sectional views showing a manufacturing process of the semiconductor device of FIGS. 12A and 12B.

### DESCRIPTION OF THE PREFERRED EMBODIMENTS

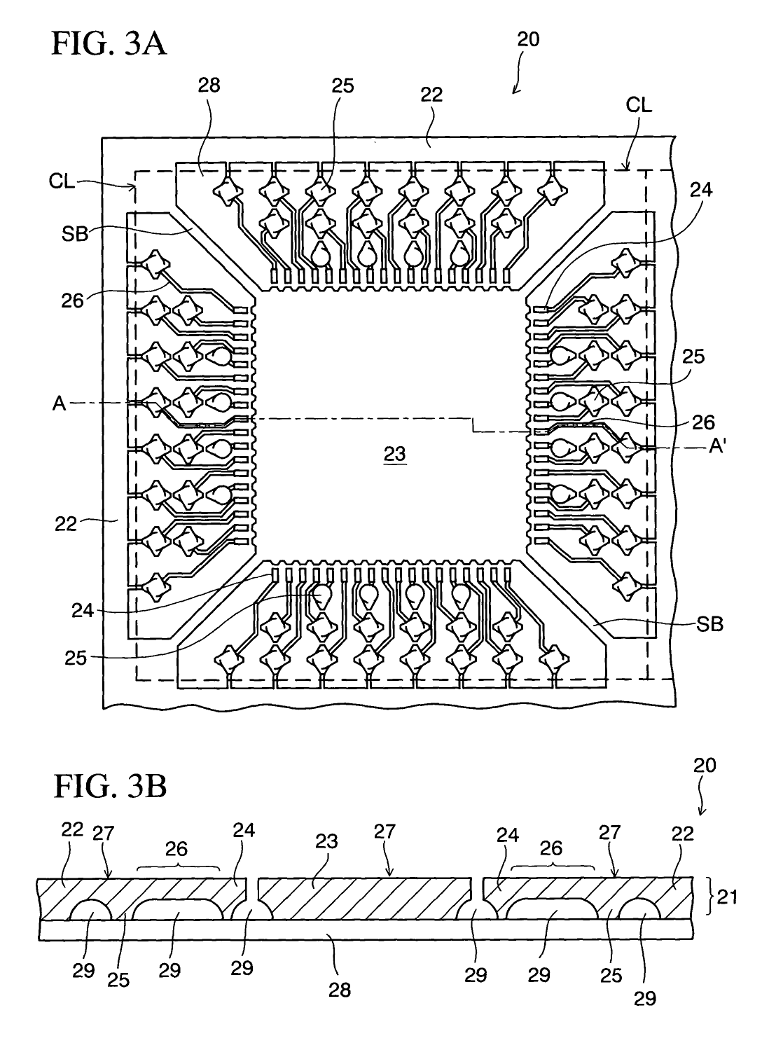

FIGS. 3A and 3B schematically show a constitution of a lead frame according to a first embodiment of the present invention. FIG. 3A shows a constitution of part of the lead frame as viewed in a plane, and FIG. 3B shows a cross-sectional structure of the lead frame taken along a line A-A′ of FIG. 3A.

In FIGS. 3A and 3B, reference numeral 20 denotes a portion of a lead frame used as a substrate of a leadless package (semiconductor device) such as QFN. The lead frame 20 basically consists of a base frame 21 obtained by etching a metal plate. In the base frame 21, reference numeral 22 denotes a frame portion. For each semiconductor element (chip) to be mounted, a tetragonal die-pad portion 23 where the semiconductor element (chip) is to be mounted is located in the center of an opening defined by the corresponding parts of the frame portion 22. The die-pad portion 23 is supported by four support bars SB extending from four corners of the corresponding parts of the frame portion 22. Reference numeral 24 denotes a wire bonding portion arranged along the periphery of the die-pad portion 23; reference numeral 25 denotes a land-like external terminal portion arranged in a region outside the wire bonding portion 24; and reference numeral 26 denotes a linear connection lead portion integrally joining the wire bonding portion 24 to the corresponding external terminal portion 25. The number of arrangement of the external terminal portion 25 is properly selected in accordance with the size of the semiconductor element (chip) to be mounted or the number of external connection terminals required for the element.

Also, a metal film 27 is formed on the entire surface of the base frame 21, and an adhesive tape 28 is attached to the surface (lower surface in the example of FIG. 3B) of the base frame 21 opposite to the side where the semiconductor element (chip) is mounted. The adhesive tape 28 supports the frame portion 22, the die-pad portion 23, the wire bonding portion 24 and the external terminal portion 25. In addition, the adhesive tape 28 has a function of supporting the individual external terminal portions 25 which are to be separated from the frame portion 22 so that they do not fall off, at the time of cutting off the portions which join the die-pad portion 23 to the individual wire bonding portions 24, and the portions which join the adjacent external terminal portions 25 in the manufacturing process of the lead frame 20 as described later. Attachment (taping) of the adhesive tape 28 is performed as a countermeasure for preventing a leakage (also called “mold flush”) of sealing resin to a back surface of the frame in molding in the package assembly process to be performed in a later stage.

Also, reference numeral 29 denotes a recess portion formed by half etching as described later. Positions where the respective recess portions 29 are formed are selected at the portions except the die-pad portion 23, the wire bonding portion 24, the external terminal portion 25, and the frame portion 22, namely, at the portions joining the die-pad portion 23 and the wire respective bonding portions 24, the portions joining the frame portion 22 and the respective external terminal portions 25, the portions joining the adjacent external terminal portions 25, and the respective connection lead portions 26.

Dashed line CL in FIG. 3A indicates a division line defining a region to be finally divided as a semiconductor device for the die-pad portion 23. The lead frame 20 is divided into packages (semiconductor devices) along the division line CL as described later.

The lead frame 20 of this embodiment is characterized in that the portion (wire bonding portion 24) to which the bonding wire is connected and the portion (external terminal portion 25) used as the external connection terminal are arranged separately from each other, and that both of the portions are integrally joined to each other by the linear connection lead portion 26. Herein, the connection lead portion 26 is formed to be thinner than the wire bonding portion 24 and the external terminal portion 25. The wire bonding portion 24 and the external terminal portion 25 have the same thickness (see FIG. 3B).

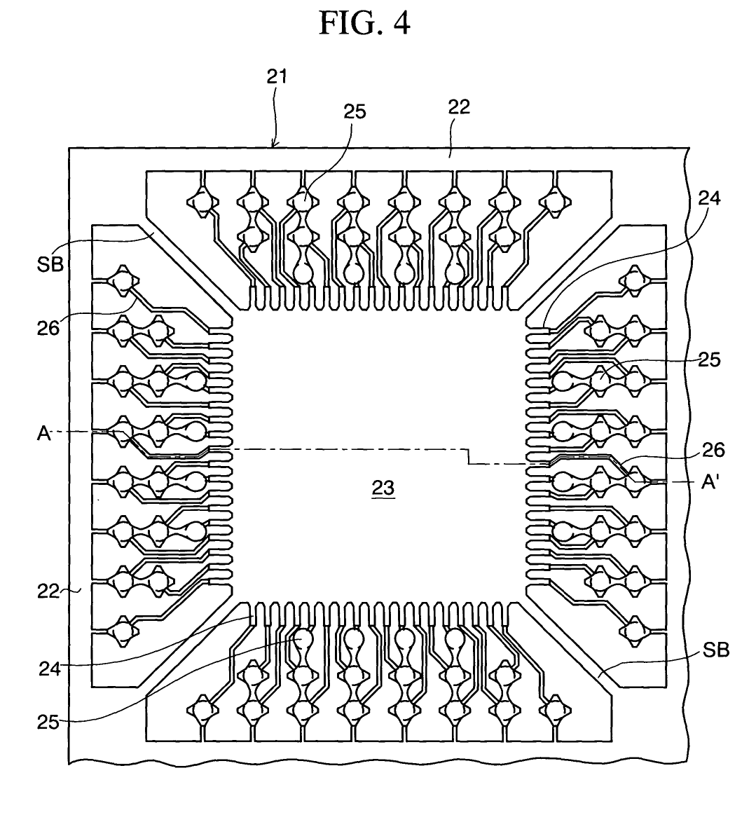

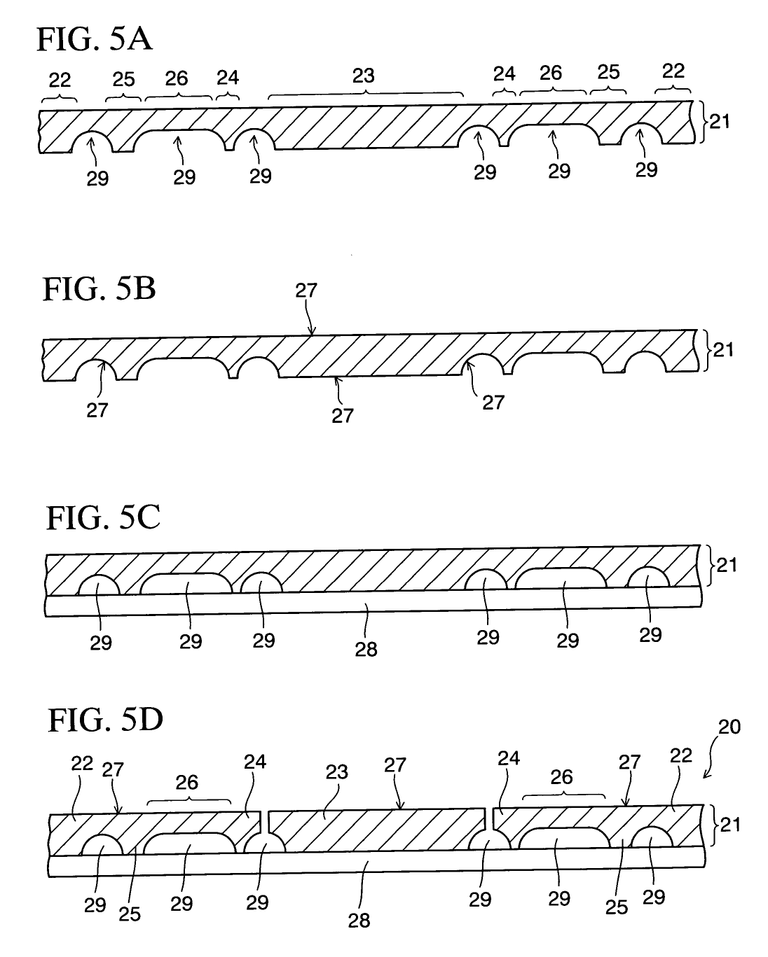

Next, a method of manufacturing the lead frame 20 according to this embodiment will be described with reference to FIG. 4 and FIGS. 5A to 5D, which sequentially show an example of a manufacturing process thereof. FIGS. 5A to 5D show a cross sectional structure taken along the line A-A′ of FIG. 4.

First, in the first step (see FIG. 4), a metal plate is etched to form the base frame 21.

The base frame 21 to be formed, as schematically shown in FIG. 4, has a structure as follows. In a region between the die-pad portion 23, which is defined for each semiconductor element to be mounted, and the frame portion 22, the plurality of wire bonding portions 24, the plurality of land-like external terminal portions 25 and the linear connection lead portions 26 are arranged. Herein, the plurality of wire bonding portions 24 are located along the periphery of the die-pad portion 23 and joined to the die-pad portion 23. The plurality of external terminal portions 25 are located outside the wire bonding portions 24 and joined to each other. Each of the connection lead portions 26 integrally joins each of the wire bonding portions 24 to the corresponding external terminal portion 25. Furthermore, the support bars SB joining the die-pad portion 23 to the frame portion 22 are arranged.

As a material of the metal plate, for example, copper (Cu), Cu based alloy, iron-nickel (Fe—Ni), Fe—Ni based alloy, or the like, is used. Selected thickness of the metal plate (base frame 21) is approximately 200 μm.

In the next step (see FIG. 5A), the recess portions 29 are formed by half etching at the predetermined portions of one surface (the lower surface in the illustrated example) of the base frame 21.

The predetermined portions (the portions where the recess portions 29 are formed) are selected at the portions except the die-pad portion 23, the wire bonding portions 24, the external terminal portions 25 and the frame portion 22. In other words, the recess portions 29 are formed at the portions joining the die-pad portion 23 and the wire bonding portions 24, the portions joining the frame portion 22 and the external terminal portions 25, the portions joining the external terminal portions 25 to each other, and the connection lead portions 26.

The half etching can be performed, for example, by wet etching after the portions of the base frame 21 except the aforementioned predetermined portions are covered with a mask (not shown). The recess portions 29 are formed to have a depth of approximately 150 μm.

In the next step (see FIG. 5B), the metal film 27 is formed by electroplating on the entire surface of the base frame 21 in which the recess portions 29 are formed.

For example, using the base frame 21 as an electric supply layer, the surface of the base frame 21 is plated with nickel (Ni) for improving adhesion, and palladium is then plated on the Ni layer for improving conductivity, followed by plating by gold (Au) flash on the Pd layer, to thereby form the metal film (Ni/Pd/Au) 27.

In this embodiment, the metal film 27 is formed in the middle of the manufacturing process of the lead frame 20 as described above, but the formation of the metal film 27 is not limited to this stage. For example, after resin sealing is performed in the package (semiconductor device) assembly process and the supporting adhesive tape of the lead frame 20 is then peeled off as described later, a solder film (metal film) may be formed on the metal portions (external terminal portions, wire bonding portions, and the like) exposed from the sealing resin, by electroless plating, printing, or the like.

In the next step (see FIG. 5C), the adhesive tape 28 including epoxy resin or polyimide resin is attached to the surface (the lower surface in the illustrated example) of the base frame 21 where the recess portions 29 are formed (taping).

In the final step (see FIG. 5D), among the portions of the base frame 21 where the recess portions 29 are formed, the portions joining the die-pad portions 23 to the wire bonding portions 24, and the portions joining the external terminal portions 25 to each other, are cut off, for example, by punching with a die (punch), a blade, or the like. The lead frame 20 (FIGS. 3A and 3B) according to this embodiment is thus produced.

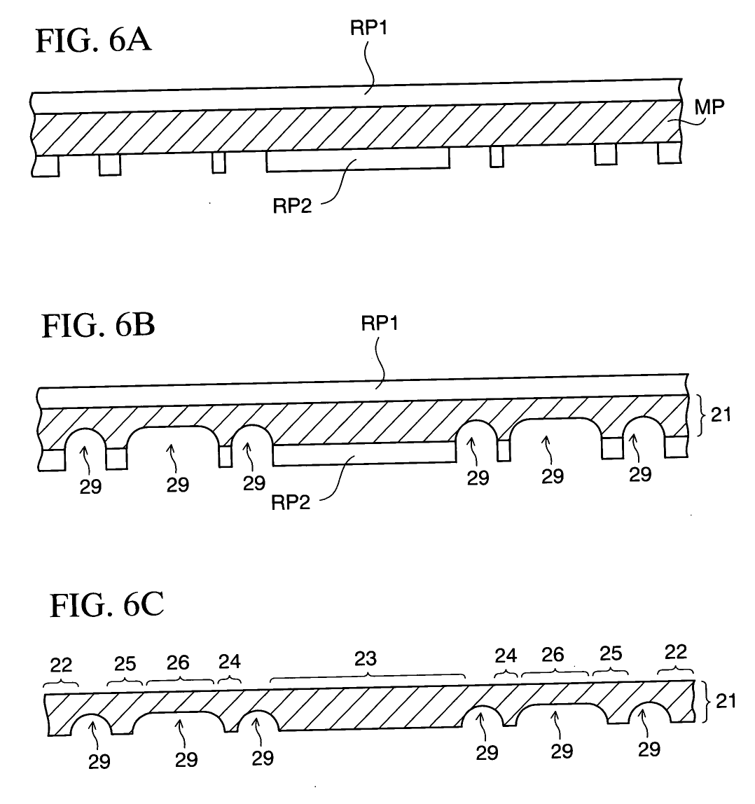

In the method (FIG. 4 and FIGS. 5A to 5D) of manufacturing the lead frame 20 according to the above described embodiment, the base frame 21 (FIG. 4) and the recess portions 29 (FIG. 5A) are formed in the different steps. However, the base frame 21 and the recess portions 29 can also be formed in one step. An example of the manufacturing process (part thereof) is shown in FIGS. 6A to 6C.

In the method exemplified in FIGS. 6A to 6C, first, both surfaces of a metal plate MP (for example, Cu or Cu-based alloy plate) are coated with etching resists, and the resists are patterned using masks (not-shown) to a predetermined shape, thereby forming resist patterns RP1 and RP2 (FIG. 6A).

In this case, as for the resist pattern RP1 on the upper side (the side where the semiconductor element is to be mounted), the resist is patterned to expose regions of the metal plate MP corresponding to the portions joining the die-pad portion 23 to the wire bonding portions 24 and the portions joining the external terminal portions to each other. On the other hand, as for the resist pattern RP2 on the lower side, the resist is patterned to expose regions of the metal plate MP corresponding to the portions to be the recess portions 29.

After both of the surfaces of the metal plate MP are covered with the resist patterns RP1 and RP2, the pattern (die-pad portion 23, wire bonding portions 24, external terminal portions 25, connection lead portions 26, and the like) as shown in FIG. 4, and the recess portions 29 are simultaneously formed by etching (for example, wet etching) (FIG. 6B).

Furthermore, the etching resists (RP1, RP2) are removed to obtain the base frame 21 of the structure as shown in FIG. 5A (FIG. 6C). The subsequent steps are the same as the steps after the step shown in the FIG. 5B.

According to the method exemplified in FIGS. 6A to 6C, since the base frame 21 and the recess portions 29 are formed in one step, the process can be simplified compared with the case of the manufacturing method according to the aforementioned embodiment (FIG. 4 and FIGS. 5A to 5D).

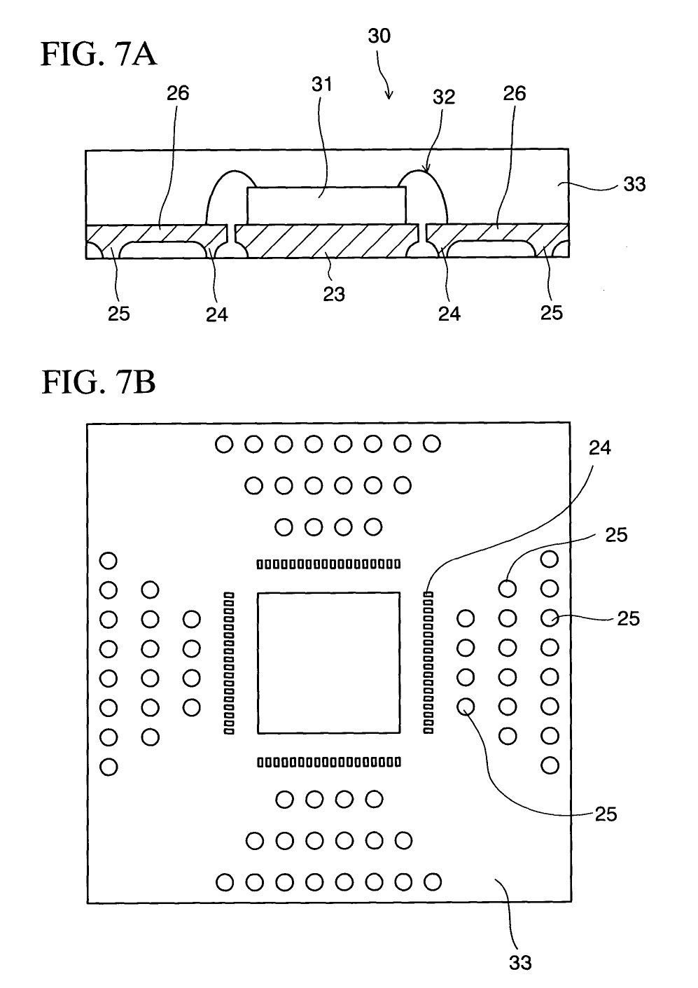

FIGS. 7A and 7B schematically show a constitution of a semiconductor device with the QFN package structure manufactured using the lead frame 20 according to the above described embodiment. FIG. 7A shows the constitution of the semiconductor device 30 as viewed in a cross section. FIG. 7B shows the constitution of the semiconductor device 30 as viewed from a back surface (mounting surface).

In the illustrated semiconductor device 30, reference numeral 31 denotes a semiconductor element (chip) mounted on the die-pad portion 23; reference numeral 32 denotes a bonding wire connecting each electrode terminal of the semiconductor element 31 to an upper surface of each wire bonding portion 24 arranged along the periphery of the die-pad portion 23; and reference numeral 33 denotes sealing resin for protecting the semiconductor element 31, the bonding wire 32, and the like. Bottom surfaces of the external terminal portions 25, which are integrally joined to the respective wire bonding portions 24 via the connection lead portions 26, are exposed to the surface of the sealing resin 33 together with bottom surfaces of the wire bonding portions 24. Herein, the package (QFN) in which the external terminal portions 25 are arranged outside the region where the semiconductor element 31 is mounted, is called a “fan-out type” package.

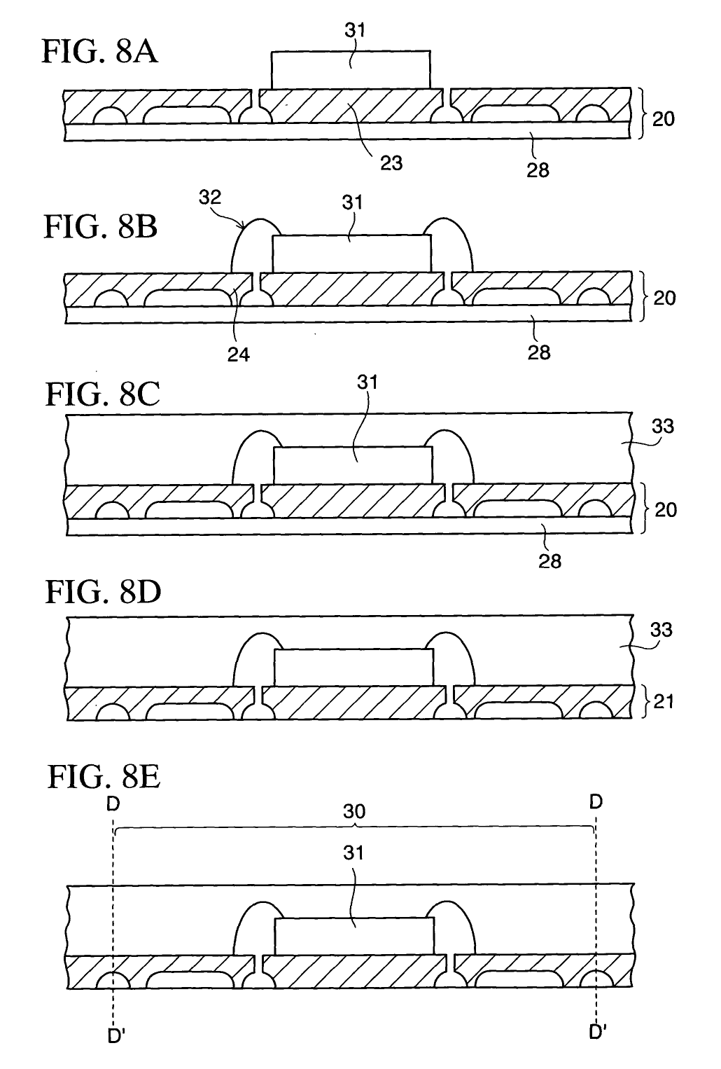

Next, a method of manufacturing the semiconductor device 30 will be described with reference to FIGS. 8A to 8E, which show a manufacturing process thereof.

First, in the first step (see FIG. 8A), the lead frame 20 is held with a fixture (not shown) while the surface thereof, where the adhesive tape 28 is attached to, is down, and the semiconductor element (chips) 31 is mounted on the die-pad portion 23 of the lead frame 20. Concretely, the die-pad portion 23 is coated with adhesive such as epoxy resin, and while the back surface of the semiconductor element 31 (the surface opposite to the side where the electrode terminals are formed) is down, the semiconductor element 31 is adhered to (mounted on) the die-pad portion 23 by the adhesive. The illustrated example shows the state in which one semiconductor element 31 is mounted on one die-pad portion 23, for simplification.

In the next step (see FIG. 8B), each electrode terminal of the semiconductor element 31 and the corresponding wire bonding portion 24 are electrically connected with each bonding wire 32.

In the next step (see FIG. 8C), the entire surface of the lead frame 20 on the side where the semiconductor elements 31 are mounted is sealed with the sealing resin 33 by mass molding. Although not shown, the lead frame 20 is placed on a lower die of a pair of molding dies to be sandwiched with an upper die from above, and while the molding dies are filled with sealing resin, heating and pressurization are performed. As a sealing technique, for example, transfer molding is used.

In the next step (see FIG. 8D), the lead frame 20 (FIG. 8C) sealed with the sealing resin 33 is take out from the molding dies, and then the adhesive tape 28 is peeled off from the lead frame 20.

In the final step (see FIG. 8E), the lead frame is divided into packages along the division line D-D′ indicated by dashed line, by means of a dicer or the like, such that each package includes one semiconductor element 31, thus obtaining the semiconductor device 30 (FIG. 7A). The division line D-D′ shown in the drawing corresponds to the division line CL shown by the dashed line in FIG. 3A.

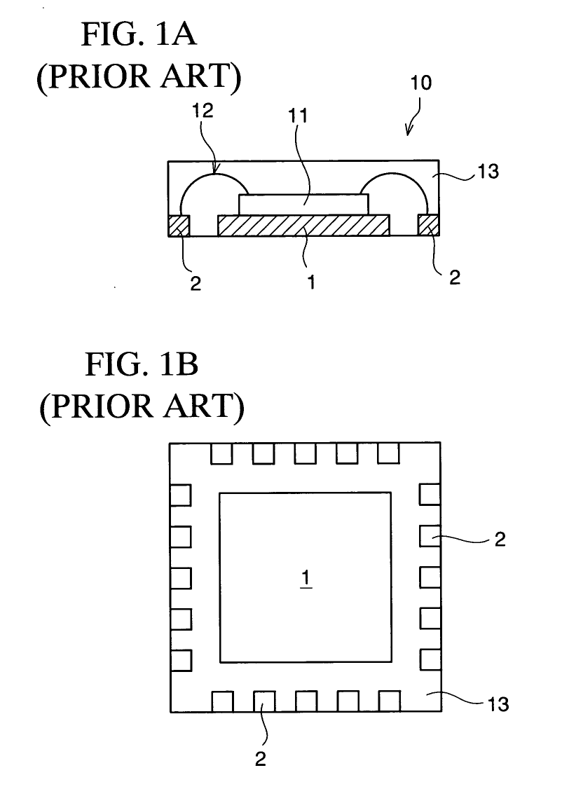

As described above, according to the first embodiment (lead frame 20, manufacturing method thereof, and semiconductor device 30 manufactured using the lead frame 20) of the present invention, the plurality of land-like external terminal portions 25 used as the external connection terminals are arranged in the region outside the wire bonding portions 24, which are arranged along the periphery of the die-pad portion 23 defined for each semiconductor element 31 to be mounted. Accordingly, compared with the prior art (FIGS. 1A and 1B) in which the lead portions (external connection terminals) 2 are arranged in a row along the periphery of each package, the number of terminals can be increased.

In addition, the portions (wire bonding portions 24) to which the bonding wires are connected and the portions (external terminal portions 25) used as the external connection terminals are arranged separately from each other, and both of the portions are integrally joined by the respective linear connection lead portions 26. In this case, since the wire bonding portions 24 are arranged along the periphery of the die-pad portion 23 (namely, at the positions near the electrode terminals of the semiconductor element 31 to be mounted), the length of the wires 32 connecting the semiconductor element 31 and the wire bonding portions 24 (namely, external terminal portions 25) can be minimized. Accordingly, the disadvantages such as a short-circuit between wires or a lowering of reliability, as encountered in the prior art, can be eliminated. As a result, the yield can be increased, and the cost can be reduced.

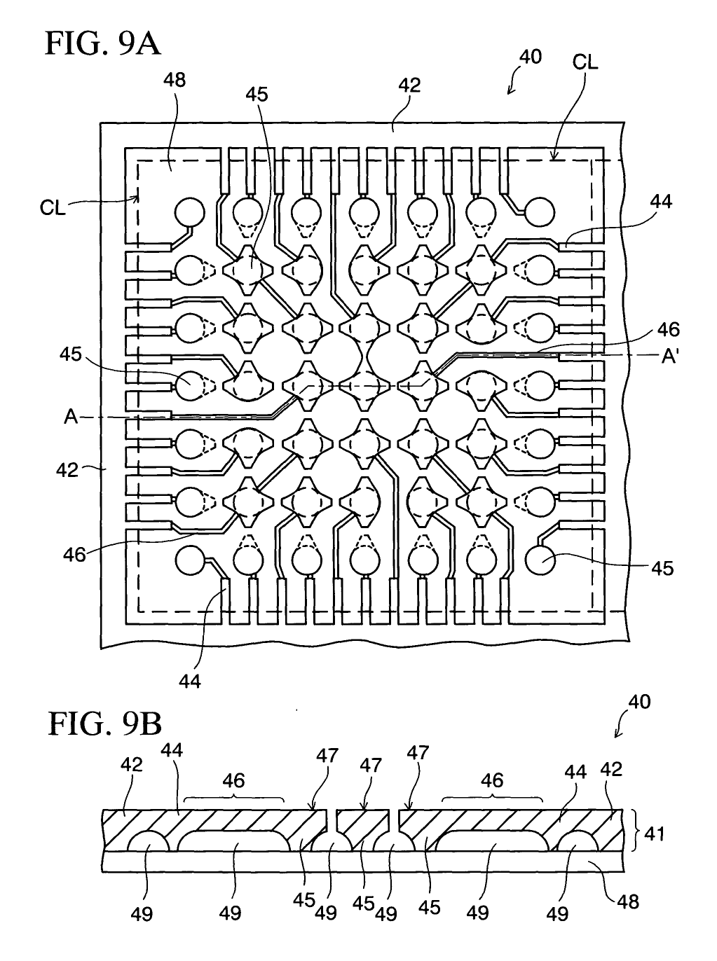

FIGS. 9A and 9B schematically show a constitution of a lead frame according to a second embodiment of the present invention. FIG. 9A shows a constitution of part of the lead frame as viewed in a plane, and FIG. 9B shows a cross-sectional structure of the lead frame taken along a line A-A′ of FIG. 9A.

In FIGS. 9A and 9B, reference numeral 40 denotes a lead frame (part thereof), reference numeral 41 denotes a base frame, reference numeral 42 denotes a frame portion, reference numeral 44 denotes a wire bonding portion, reference numeral 45 denotes an external terminal portion, reference numeral 46 denotes a connection lead portion, reference numeral 47 denotes a metal film, reference numeral 48 denotes an adhesive tape, and reference numeral 49 denotes a recess portion. They correspond to the lead frame 20, the base frame 21, the frame portion 22, the wire bonding portion 24, the external terminal portion 25, the connection lead portion 26, the metal film 27, the adhesive tape 28, and the recess portion 29, respectively, in FIG. 3,

The lead frame 40 according to this embodiment differs from the lead frame 20 according to the embodiment of FIG. 3 in the following points. The die-pad portion 23 is not provided. The support bars SB are not provided. The plurality of wire bonding portions 44 are arranged within a region which is to be finally divided as a semiconductor device for each semiconductor element to be mounted (a region defined by the division line CL indicated by dashed line in the drawing) along the outer periphery of the region. The plurality of land-like external terminal portions 45 are arranged in a region inside the wire bonding portions 44. As for the other constitutions, the lead frame 40 is basically the same as the case of the embodiment of FIG. 3, and thus the description thereof is omitted.

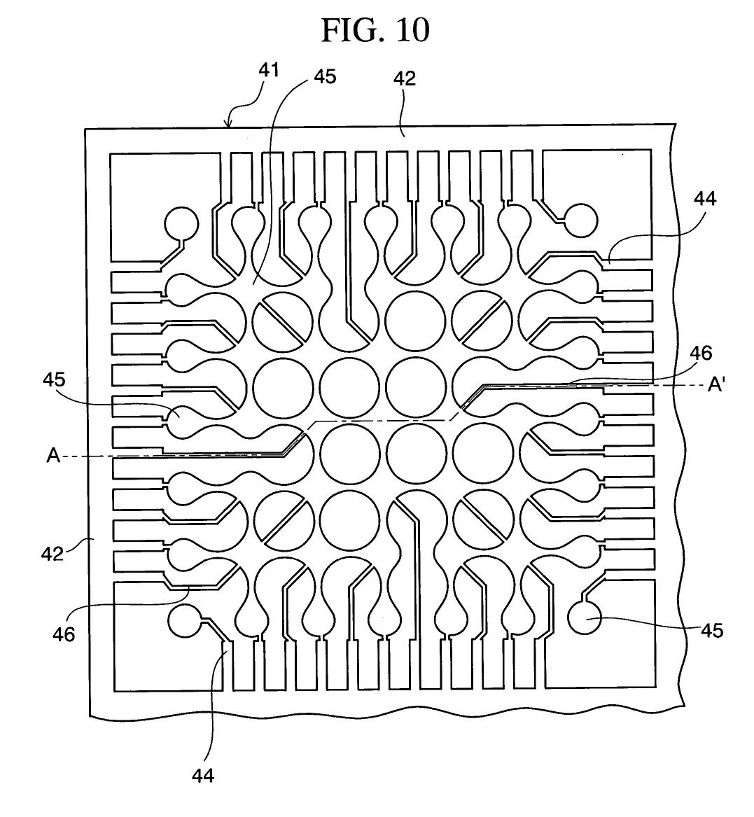

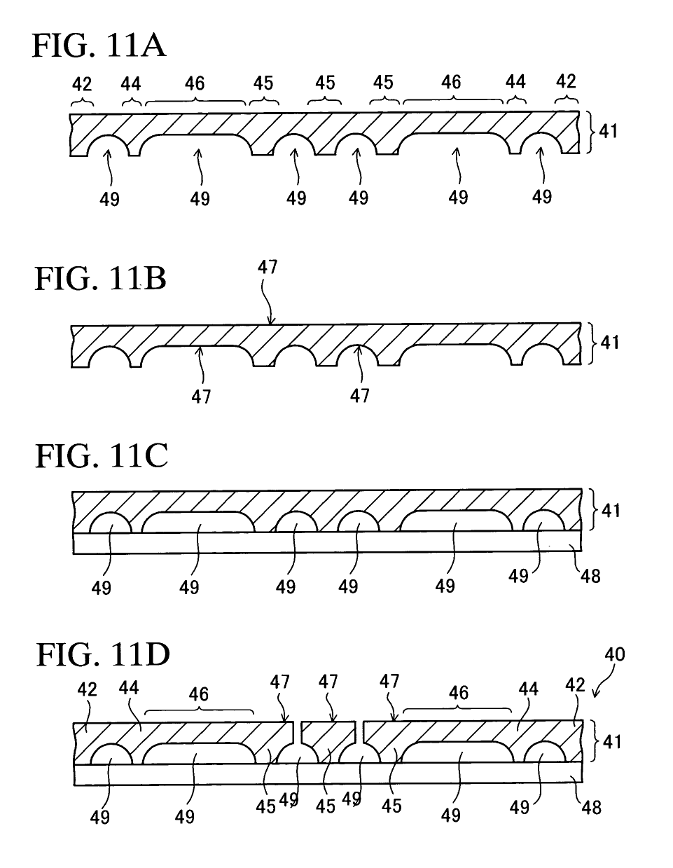

Next, a method of manufacturing the lead frame 40 according to this embodiment will be described with reference to FIG. 10 and FIGS. 11A to 11D, which sequentially show an example of a manufacturing process thereof. FIGS. 11A to 11D show a cross-sectional structure taken along the line A-A′ of FIG. 10.

First, in the first step (see FIG. 10), a metal plate is etched to form the base frame 41.

The base frame 41 to be formed, as schematically shown in FIG. 10, has a structure as follows. In a region surrounded by the frame portions 42 for each semiconductor device to be mounted, the plurality of wire bonding portions 44, the plurality of land-like external terminal portions 45 and the linear connection lead portions 46 are arranged. Herein, the plurality of wire bonding portions 44 are located along the outer periphery of the region and joined to the frame portion 42. The plurality of external terminal portions 45 are located inside the wire bonding portions 44 and joined to each other. Each of the connection lead portions 46 integrally joins each of the wire bonding portions 44 to the corresponding external terminal portion 45. As a material of the metal plate, similarly to the case of the first embodiment, Cu, Cu based alloy, Fe—Ni, Fe—Ni based alloy, or the like, is used. Selected thickness of the metal plate is approximately 200 μm.

In the next step (see FIG. 11A), the recess portions 49 are formed by half etching at the predetermined portions in one surface (the lower surface in the example of the drawing) of the base frame 41.

The predetermined portions (portions where the recess portions 49 are formed) are selected at the portions except the wire bonding portions 44, the external terminal portions 45 and the frame portion 42, namely, at the portions joining the frame portion 42 and the wire bonding portions 44, the portions joining the external terminal portions 45 to each other, and the connection lead portions 46. Similarly to the case of the first embodiment, the half etching can be performed by wet etching after the portions of the base frame 41 except the aforementioned predetermined portions are covered with a mask (not shown).

In the next step (see FIG. 11B), the metal film 47 is formed on the entire surface of the base frame 41 in which the recess portions 49 are formed. The method of forming the metal film 47 is similar to that (step of FIG. 5B) in the case of the first embodiment.

In the next step (see FIG. 1C), the adhesive tape 48 including epoxy resin or polyimide resin is attached to the surface (lower surface in the example of the drawing) of the base frame 41 where the recess portions 49 are formed (taping).

In the final step (see FIG. 1D), among the portions of the base frame 41 where the recess portions 49 are formed, the portions joining the external terminal portions 45 to each other are cut off with a die (punch), a blade, or the like. The lead frame 40 (FIGS. 9A and 9B) according to this embodiment is thus produced.

Also in the method (FIG. 10 and FIGS. 11A to 11D) of manufacturing the lead frame 40 according to the second embodiment, which is not shown in the drawing, the base frame 41 and the recess portions 49 can be formed in one step as in the case of the manufacturing process exemplified in FIGS. 6A to 6C.

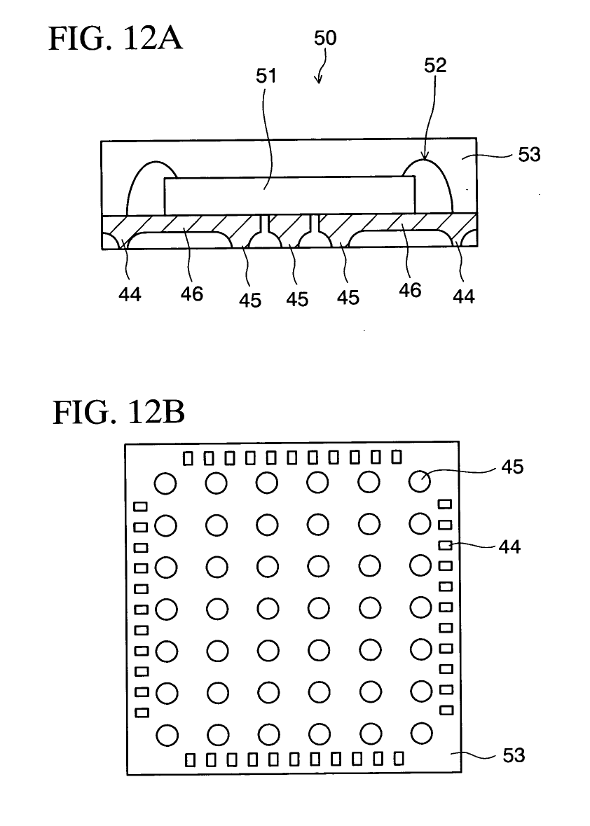

FIGS. 12A and 12B schematically show a constitution of a semiconductor device with a QFN package structure manufactured using the lead frame 40 according to the second embodiment. FIG. 12A shows a constitution of a semiconductor device 50 in a cross section, and FIG. 12B shows the constitution of the semiconductor device 50 as viewed from the back surface (mounting surface).

In the illustrated semiconductor device 50, reference numeral 51 denotes a semiconductor element (chip) mounted on a required number of external terminal portions 45 among the plurality of external terminal portions 45 so as to keep isolated from the required number of external terminal portions. Reference numeral 52 denotes a bonding wire connecting each electrode terminal of the semiconductor elements 51 to an upper surface of each wire bonding portion 44 arranged along the periphery of the semiconductor element 51. Reference numeral 53 denotes sealing resin for protecting the semiconductor element 51, the bonding wire 52, and the like. Bottom surfaces of the external terminal portions 45, which are integrally connected to the respective wire bonding portions 44 via the connection lead portions 46, are exposed to the surface of the sealing resin 53 together with bottom surfaces of the wire bonding portions 44. Herein, the package (QFN) which includes the external terminal portions 45 inside the region where the semiconductor element 51 is mounted, is called a “fan-in type” package.

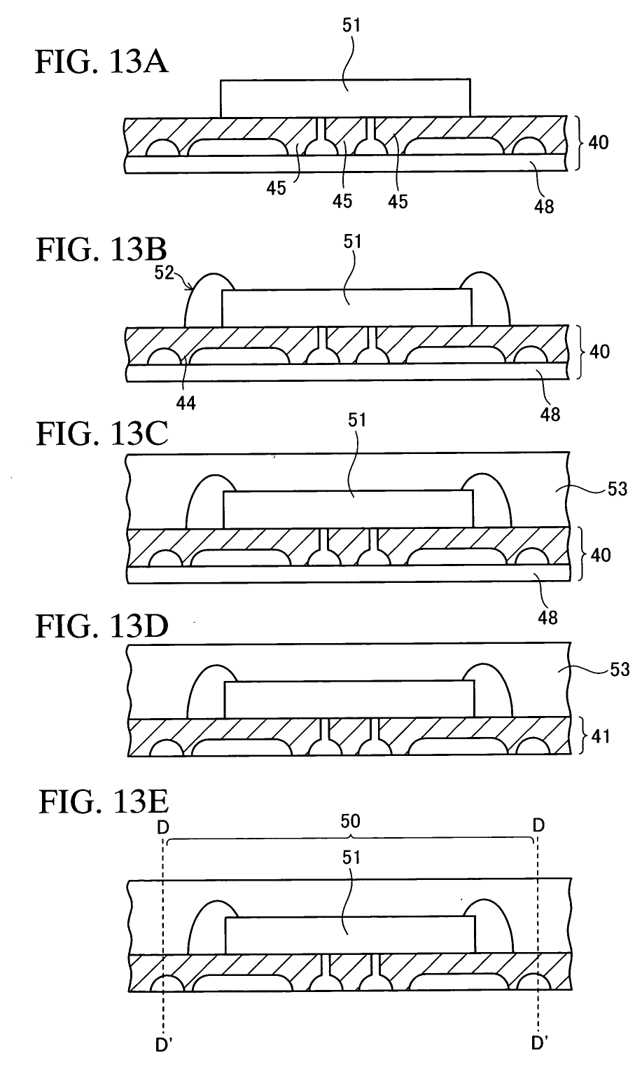

Next, a method of manufacturing the semiconductor device 50 will be described with reference to FIGS. 13A to 13E, which show a manufacturing process thereof.

First, in the first step (see FIG. 13A), the lead frame 40 is held with a fixture (not shown) while the surface thereof, where the adhesive tape 48 is attached to, is down, and the semiconductor element 51 is mounted on the required number of external terminal portions 45 of the lead frame 40. The mounting method is the same as that in the case of the first embodiment (step of FIG. 8A).

In the next step (see FIG. 13B), each electrode terminal of the semiconductor element 51 and the corresponding wire bonding portion 44 are electrically connected with each bonding wire 52.

In the next step (see FIG. 13C), the entire surface of the lead frame 40 on the side where the semiconductor elements 51 are mounted is sealed with the sealing resin 53 by mass molding. The sealing method is the same as that in the case of the first embodiment (step of FIG. 8C).

In the next step (see FIG. 13D), the lead frame 40 (FIG. 13C) sealed with the sealing resin 53 is take out from the molding dies, and then the adhesive tape 48 is peeled off from the lead frame 40.

In the final step (see FIG. 13E), the lead frame is divided into packages along the division line D-D′ indicated by dashed line, by means of a dicer or the like, such that each package includes one semiconductor element 51, thus obtaining the semiconductor device 50 (FIG. 12A). The division line D-D′ shown in the drawing correspond to the division line CL shown by the dashed line in FIG. 9A.

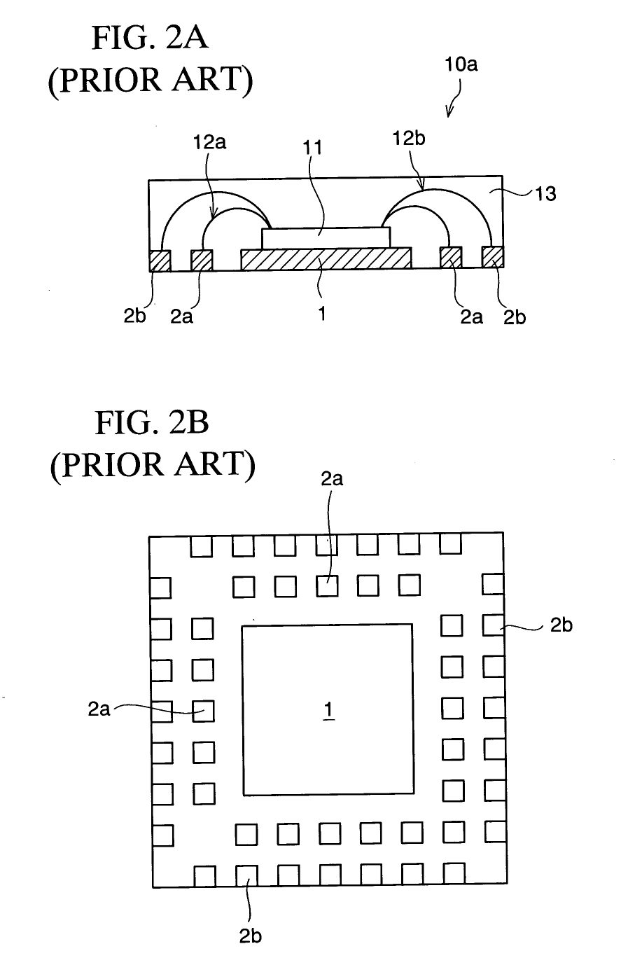

As described above, according to the second embodiment (lead frame 40, manufacturing method thereof, and semiconductor device 50 manufactured using the lead frame 40) of the present invention, the plurality of land-like external terminal portions 45 used as the external connection terminals are arranged in the region inside the wire bonding portions 44, which is arranged along the outer periphery of the region to be finally divided as the semiconductor device for the semiconductor element 51 to be mounted. Accordingly, compared with the prior art (FIGS. 1A, 1B, and FIGS. 2A, 2B) in which the external connection terminals (lead portions) are not allowed to be arranged under the mounting surface of the semiconductor element, the number of terminals can be increased.

Moreover, similarly to the case of the first embodiment, the wire bonding portions 44 and the external terminal portions 45 are arranged separately from each other, and both of the portions are integrally joined to each other by the linear connection lead portions 46. In this case, the wire bonding portions 44 are arranged along the outer periphery of the region to be finally divided as the semiconductor device for the semiconductor element 51 to be mounted (namely, arranged at the positions near the electrode terminals of the semiconductor element 51 to be mounted). Accordingly, the length of the wires 52 connecting the semiconductor element 51 and the wire bonding portions 44 (namely, external terminal portions 45) can be minimized. Thus, the yield can be increased, and the cost can be reduced.

Furthermore, the QFN of “fan-in type” according to the second embodiment has an advantage in that the package can be reduced in size compared with the QFN of “fan-out type” according to the first embodiment if the numbers of external terminal portions thereof are equal to each other.

What is claimed is:

1. A lead frame comprising:
a die-pad portion defined for a semiconductor element to be mounted;
a plurality of wire bonding portions arranged along a periphery of the die-pad portion within a region to be finally divided as a semiconductor device for the die-pad portion;
a plurality of land-like external terminal portions arranged in a region outside the wire bonding portions; and
a plurality of linear connection lead portions each integrally joining each of the wire bonding portions to a corresponding one of the external terminal portions,
wherein the die-pad portion, the wire bonding portions and the external terminal portions are supported by an adhesive tape.

2. The lead frame according to claim 1, wherein each of the connection lead portions is formed to be thinner than each of the wire bonding portions and each of the external terminal portions, and each of the wire bonding portions is formed to be as thick as each of the external terminal portions.

3. A lead frame comprising:
a plurality of wire bonding portions arranged within a region to be finally divided as a semiconductor device for a semiconductor element to be mounted, and along an outer periphery of the region;
a plurality of land-like external terminal portions arranged in a region inside the wire bonding portions; and
a plurality of linear connection lead portions each integrally joining each of the wire bonding portions to a corresponding one of the external terminal portions,
wherein the wire bonding portions and the external terminal portions are supported by an adhesive tape.

4. The lead frame according to claim 3, wherein each of the connection lead portions is formed to be thinner than each of the wire bonding portions and each of the external terminal portions, and each of the wire bonding portions is formed to be as thick as each of the external terminal portions.

5. A method of manufacturing a lead frame, comprising the steps of:
forming a base frame by etching a metal plate, the base frame including a plurality of wire bonding portions, a plurality of land-like external terminal portions and a plurality of linear connection lead portions arranged in a region between a die-pad portion and a frame portion for a semiconductor element to be mounted, said plurality of wire bonding portions being located along a periphery of the die-pad portion and joined to the die-pad portion, said plurality of external terminal portions being located outside the wire bonding portions and joined to each other, said plurality of connection lead portions each integrally joining each of the wire bonding portions to a corresponding one of the external terminal portions;
forming recess portions by half etching, in portions other than the die-pad portion, the wire bonding connection portions, the external terminal portions and the frame portion, of one surface of the base frame;
attaching an adhesive tape to the surface of the base frame where the recess portions are formed; and
cutting off portions joining the die-pad portion and the wire bonding portions, and portions joining the external terminal portions to each other, among the portions of the base frame where the recess portions are formed.

6. The method according to claim 5, further comprising a step of forming a metal film on an entire surface of the base frame, after forming the recess portions, and before attaching the adhesive tape.

7. A method of manufacturing a lead frame, comprising the steps of:
forming a base frame by simultaneously etching both surfaces of a metal plate using resists patterned into predetermined shapes, respectively, the base frame including a plurality of wire bonding portions, a plurality of land-like external terminal portions and a plurality of linear connection lead portions arranged in a region between a die-pad portion and a frame portion for a semiconductor element to be mounted, said plurality of wire bonding portions being located along a periphery of the die-pad portion and joined to the die-pad portion, said plurality of external terminal portions being located outside the wire bonding portions and joined to each other, said plurality of connection lead portions each integrally joining each of the wire bonding portions to a corresponding one of the external terminal portions, and simultaneously forming recess portions in portions other than the die-pad portion, the wire bonding connection portions, the external terminal portions and the frame portion, of one surface of the base frame;
attaching an adhesive tape to the surface of the base frame where the recess portions are formed; and
cutting off portions joining the die-pad portion and the wire bonding portions, and portions joining the external terminal portions to each other, among the portions of the base frame where the recess portions are formed.

8. The method according to claim 7, further comprising a step of forming a metal film on an entire surface of the base frame, after forming the recess portions, and before attaching the adhesive tape.

9. A method of manufacturing a lead frame, comprising the steps of:
forming a base frame by etching a metal plate, the base frame including a plurality of wire bonding portions, a plurality of land-like external terminal portions and a plurality of linear connection lead portions arranged in a region surrounded by a frame portion for a semiconductor element to be mounted, said plurality of wire bonding portions being located along an outer periphery of the region and joined to the frame portion, said plurality of external terminal portions being located inside the wire bonding portions and joined to each other, said plurality of connection lead portions each integrally joining each of the wire bonding portions to a corresponding one of the external terminal portions;
forming recess portions by half etching, in portions other than the external terminal portions, the wire bonding portions and the frame portion, of one surface of the base frame;
attaching an adhesive tape to the surface of the base frame where the recess portions are formed; and
cutting off portions joining the external terminal portions to each other, among the portions of the base frame where the recess portions are formed.

10. The method according to claim 9, further comprising a step of forming a metal film on an entire surface of the base frame, after forming the recess portions, and before attaching the adhesive tape.

11. A method of manufacturing a lead frame, comprising the steps of:
forming a base frame by simultaneously etching both surfaces of a metal plate using resists patterned into predetermined shapes, respectively, the base frame including a plurality of wire bonding portions, a plurality of land-like external terminal portions and a plurality of linear connection lead portions arranged in a region surrounded by a frame portion for a semiconductor element to be mounted, said plurality of wire bonding portions being located along an outer periphery of the region and joined to the frame portion, said plurality of external terminal portions being located inside the wire bonding portions and joined to each other, said plurality of connection lead portions each integrally joining each of the wire bonding portions to a corresponding one of the external terminal portions, and simultaneously forming recess portions in portions other than the external terminal portions, the wire bonding connection portions and the frame portion, of one surface of the base frame;
attaching an adhesive tape to the surface of the base frame where the recess portions are formed; and
cutting off portions joining the external terminal portions to each other, among the portions of the base frame where the recess portions are formed.

12. The method according to claim 11, further comprising a step of forming a metal film on an entire surface of the base frame, after forming the recess portions, and before attaching the adhesive tape.

13. A semiconductor device comprising:
a die-pad portion;
a plurality of wire bonding portions arranged along a periphery of the die-pad portion;
a plurality of land-like external terminal portions arranged outside the wire bonding portions;
a plurality of linear connection lead portions each integrally joining each of the wire bonding portions to a corresponding one of the external terminal portions; and
a semiconductor element mounted on the die-pad portion,
wherein each of electrode terminals of the semiconductor element is connected to a top surface of a corresponding one of the wire bonding portions by a bonding wire,
the semiconductor element, the bonding wire, the wire bonding portions, the external terminal portions and the connection lead portions are sealed with sealing resin, and
bottom surfaces of the external terminal portions are exposed to a surface of the sealing resin together with bottom surfaces of the wire bonding portions.

14. The semiconductor device according to claim 13, wherein each of the connection lead portions is formed to be thinner than each of the wire bonding portions and each of the external terminal portions, and each of the wire bonding portions is formed to be as thick as each of the external terminal portions.

15. A semiconductor device comprising:
a plurality of wire bonding portions arranged along a periphery of the device;
a plurality of land-like external terminal portions arranged inside the wire bonding portions;
a plurality of linear connection lead portions each integrally joining each of the wire bonding portions to a corresponding one of the external terminal portions; and
a semiconductor element mounted on a required number of external terminal portions among said plurality of external terminal portions, while keeping isolated from the required number of external terminal portions,
wherein each of electrode terminals of the semiconductor element is connected to a top surface of a corresponding one of the wire bonding portions by a bonding wire,
the semiconductor element, the bonding wire, the wire bonding portions, the external terminal portions and the connection lead portions are sealed with sealing resin, and
bottom surfaces of the external terminal portions are exposed to a surface of the sealing resin together with bottom surfaces of the wire bonding portions.

16. The semiconductor device according to claim 15, wherein each of the connection lead portions is formed to be thinner than each of the wire bonding portions and each of the external terminal portions, and each of the wire bonding portions is formed to be as thick as each of the external terminal portions.
